(19) United States
(12) Patent Application Publication
(10) Pub. No.: US 2025/0185409 A1
(43) Pub. Date: Jun. 5, 2025

(54) QUANTUM DOT, QUANTUM DOT ENSEMBLE, LIGHT DETECTION DEVICE, AND ELECTRONIC APPARATUS

(71) Applicants: SONY SEMICONDUCTOR SOLUTIONS CORPORATION, KANAGAWA (JP); SONY GROUP CORPORATION, TOKYO (JP)

(72) Inventors: SHUNSUKE YAMASHITA, TOKYO (JP); MAMORU TANABE, TOKYO (JP); SYUUITI TAKIZAWA, KANAGAWA (JP); MICHINORI SHIOMI, TOKYO (JP)

(21) Appl. No.: 18/844,136

(22) PCT Filed: Jan. 19, 2023
(86) PCT No.: PCT/JP2023/001549

§ 371 Date: Sep. 5, 2024

(30) Foreign Application Priority Data
Mar. 16, 2022 (JP) 2022-041757

(51) Int. Cl. H10F 77/14; H10F 30/222

(52) U.S. Cl. CPC H10F 77/147; H10F 30/222; H10F 77/1433

(57) ABSTRACT

A quantum dot includes a core and a shell. The core includes a compound semiconductor and has a polyhedral shape. The polyhedral shape includes multiple surfaces and a vertex at which multiple edges between the surfaces adjacent to each other converge. The shell is provided at the surfaces and has a thickness at the part around the vertex in a vertical direction with respect to any one of the surfaces. The thickness is greater than a thickness at a part other than the part around the vertex in the same direction.

### TECHNICAL FIELD

The present disclosure relates to a quantum dot, a quantum dot ensemble, a light detection device, and an electronic apparatus.

### BACKGROUND ART

A quantum dot is employed in a display phosphor or an optical sensor. The quantum dot is configured to convert a spectrum of incident light into energy output having different frequencies.

Typically, the quantum dot includes a single semiconductor nanoparticle. The surface of the semiconductor nanoparticle is covered with an organic ligand. Defects (dangling bond) existing on the surface and having high reactivity are made partially inactive owing to the organic ligand.

However, if defects remain on the surface, electron-hole recombination occurs. Thus, light emitting property or light receiving property tends to deteriorate.

NPTL 1 and NPTL 2 disclose a core-shell quantum dot. In a case of the core-shell quantum dot, the surface of a quantum dot (core) is covered with a different substance (shell). With the core-shell quantum dot, the shell makes it possible to reduce defects on the surface, which makes it possible to enhance intensity of light emission.

In addition, PTL 1 discloses a core shell particle. The core shell particle includes a core including a group III element and a group V element, and also includes a shell that covers at least a portion of a surface of the core and includes a group II element and a group VI element. This core shell particle has a tetrahedral shape in which the length of one edge is greater than or equal to 6 nm. With such a core shell particle, it is possible to achieve light emission efficiency of higher than or equal to 50%.

### CITATION LIST

### Non-Patent Literature

NPTL 1: J. Phys. Chem. 100 (1996) 468.
NPTL 2: J. Phys. Chem. B 101 (1997) 6463.

### Patent Literature

PTL 1: International Publication No. WO 2019/039305

### SUMMARY OF THE INVENTION

In a case of the core-shell quantum dot described above, it is difficult to so provide a material, which is to be a shell, on a surface of a core as to have a uniform thickness. For this reason, it is desired to research and develop a core-shell quantum dot that makes it possible to improve light emitting property or light receiving property.

A quantum dot according to a first aspect of the present disclosure includes a core and a shell. The core includes a compound semiconductor and has a polyhedral shape. The polyhedral shape includes multiple surfaces and a vertex at which multiple edges between the surfaces adjacent to each other converge. The shell is provided at the surfaces and has a thickness at the part around the vertex in a vertical direction with respect to any one of the surfaces. The thickness is greater than a thickness at a part other than the part around the vertex in the same direction.

A quantum dot ensemble according to a second aspect of the present invention includes an ensemble of quantum dot shaped in a layered shape. The quantum dot includes a core and a shell. The core includes a compound semiconductor and has a polyhedral shape. The polyhedral shape includes multiple surfaces and a vertex at which multiple edges between the surfaces adjacent to each other converge. The shell is provided at the surfaces and has a thickness at the part around the vertex in a vertical direction with respect to any one of the surfaces. The thickness is greater than a thickness at a part other than the part around the vertex in the same direction.

A light detection device according to a third aspect of the present disclosure includes a light detection element. The light detection element includes a first electrode, a photoelectric conversion layer, and a second electrode that are stacked on each other in order. The photoelectric conversion layer includes a quantum dot ensemble. The quantum dot ensemble includes an ensemble of a quantum dot shaped in a layered shape. The quantum dot includes a core and a shell. The core includes a compound semiconductor and has a polyhedral shape. The polyhedral shape includes multiple surfaces and a vertex at which multiple edges between the surfaces adjacent to each other converge. The shell is provided at the surfaces and has a thickness at the part around the vertex in a vertical direction with respect to any one of the surfaces. The thickness is greater than a thickness at a part other than the part around the vertex in the same direction.

An electronic apparatus according to a fourth aspect of the present disclosure includes a light detection element. The light detection element includes a first electrode, a photoelectric conversion layer, and a second electrode that are stacked on each other in order. The photoelectric conversion layer includes a quantum dot ensemble. The quantum dot ensemble includes an ensemble of a quantum dot shaped in a layered shape. The quantum dot includes a core and a shell. The core includes a compound semiconductor and has a polyhedral shape. The polyhedral shape includes multiple surfaces and a vertex at which multiple edges between the surfaces adjacent to each other converge. The shell is provided at the surfaces and has a thickness at the part around the vertex in a vertical direction with respect to any one of the surfaces. The thickness is greater than a thickness at a part other than the part around the vertex in the same direction.

### BRIEF DESCRIPTION OF THE DRAWINGS

FIG. 1 is a perspective view of a quantum dot according to a first embodiment of the present disclosure.

FIG. 2 is a perspective view of the quantum dot illustrated in FIG. 1 when viewed from another angle.

FIG. 3 is a perspective view corresponding to FIG. 1 and used to describe a basic shape of a core of the quantum dot illustrated in FIGS. 1 and 2.

FIG. 4 is a perspective view corresponding to FIG. 2 and used to describe a basic structure of the core and a shell of the quantum dot illustrated in FIGS. 1 and 2.

FIG. 5 is a diagram (HAADF image) of a configuration of a quantum dot ensemble including a quantum dot illustrated in FIGS. 1 and 2 shaped in a layered shape, imaged using a high-angle annular dark field scanning transmission electron microscope (HAADF-STEM: High-Angle Annular Dark Field Scanning Transmission Electron Microscope).

FIG. 6 is an enlarged diagram (HAADF image) of a configuration of one quantum dot of the quantum dot ensemble illustrated in FIG. 5.

FIG. 7 is a diagram illustrating a distribution of a shell provided on a core of the quantum dot illustrated in FIG. 6.

FIG. 8 is a first table including HAADF images used to describe configurations of quantum dots according to Examples of the first embodiment and configurations of quantum dots according to comparative examples.

FIG. 9 is a second table including HAADF images used to describe the configurations of the quantum dots according to Examples of the first embodiment and the configurations of the quantum dots according to the comparative examples.

FIG. 10 is a table used to describe characteristics of the quantum dots according to Examples of the first embodiment and characteristics of the quantum dots according to the comparative examples.

FIG. 11 is a graph illustrating a relationship between a heating temperature and a thicknesses of the shell at a part around the vertex of the core for each of the quantum dots according to Examples of the first embodiment and the quantum dots according to the comparative examples.

FIG. 12 is a perspective view corresponding to FIG. 4 and illustrating a quantum dot according to a modification example of the first embodiment.

FIG. 13 is a perspective view corresponding to FIG. 3 and used to describe a basic shape of a core of a quantum dot according to a second embodiment of the present disclosure.

FIG. 14 is a side view corresponding to FIG. 4 and used to describe a basic structure of the core and a shell of the quantum dot illustrated in FIG. 13.

FIG. 15 is a side view corresponding to FIG. 14 and illustrating a quantum dot according to a modification example of the second embodiment.

FIG. 16 is a perspective view corresponding to FIG. 3 and used to describe a basic shape of a core of a quantum dot according to a third embodiment of the present disclosure.

FIG. 17 is a side view corresponding to FIG. 4 and used to describe a basic structure of the core and a shell of the quantum dot illustrated in FIG. 16.

FIG. 18 is a side view corresponding to FIG. 17 and illustrating a quantum dot according to a modification example of the third embodiment.

FIG. 19 is a schematic view of a planar configuration of a light detection device according to a fourth embodiment of the present disclosure.

FIG. 20 is a vertical cross-sectional view of a configuration of a light detection element of the light detection device illustrated in FIG. 19.

FIG. 21 is a vertical cross-sectional view of a configuration of a light detection element of a light detection device according to a modification example of the fourth embodiment.

FIG. 22 is a schematic block diagram illustrating an electronic apparatus according to a fifth embodiment of the present disclosure.

FIG. 23 is a block diagram depicting an example of schematic configuration of a vehicle control system.

FIG. 24 is a diagram of assistance in explaining an example of installation positions of an outside-vehicle information detecting section and an imaging section.

FIG. 25 is a view depicting an example of a schematic configuration of an endoscopic surgery system.

FIG. 26 is a block diagram depicting an example of a functional configuration of a camera head and a camera control unit (CCU).

### MODES FOR CARRYING OUT THE INVENTION

Below, embodiments according to the present disclosure will be described in detail with reference to the drawings. Note that the description will be given in the following order.

### 1. First Embodiment

A first embodiment describes an example in which the present technique is applied to a quantum dot and a quantum dot ensemble. The first embodiment describes the configurations, characteristics, etc. of the quantum dot and the quantum dot ensemble.

### 2. Second Embodiment

A second embodiment describes a quantum dot and a quantum dot ensemble having configurations differing from those of the quantum dot and the quantum dot ensemble according to the first embodiment.

### 3. Third Embodiment

A third embodiment describes a quantum dot and a quantum dot ensemble having configurations differing from those of the quantum dots and the quantum dot ensembles according to the first and second embodiments.

### 4. Fourth Embodiment

A fourth embodiment describes a light detection device including the quantum dot and the quantum dot ensemble according to any of the first to third embodiments.

### 5. Fifth Embodiment

A fifth embodiment describes an electronic apparatus including the quantum dot and the quantum dot ensemble according to any of the first to third embodiments, or the light detection device according to the fourth embodiment.

### 6. Example of Application to Mobile Body

This application example describes an example in which the present technique is applied to a mobile body.

### 7. Example of Application to Endoscopic Surgery System

This application example describes an example in which the present technique is applied to an endoscopic surgery system.

### 8. Other Embodiments

### 1. First Embodiment

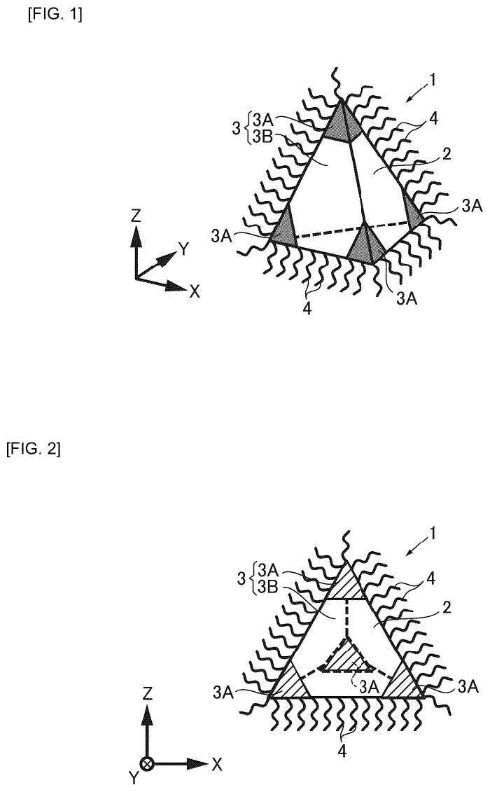

A quantum dot 1 and a quantum dot ensemble 10 according to the first embodiment of the present disclosure will be described with reference to FIGS. 1 to 12.

Here, an arrowed X direction that is illustrated in the drawings on an as-necessary basis indicates one planar direction of the quantum dot 1 or the like disposed on a plane for the purpose of convenience. An arrowed Y direction indicates another planar direction perpendicular to the arrowed X direction. In addition, an arrowed Z direction indicates an upward direction perpendicular to the arrowed X direction and the arrowed Y direction. That is, the arrowed X direction, the arrowed Y direction, and the arrowed Z direction substantially match an X axis direction, a Y axis direction, and a Z axis direction, respectively, in a three-dimensional coordinate system.

Note that each of these directions is illustrated merely for the purpose of facilitating understanding the description, and is not given for the purpose of limitation of the directions of the present technique.

### [Configuration of Quantum Dot 1]

### (1) Basic Configuration of Quantum Dot 1

FIG. 1 illustrates a configuration of one example of the quantum dot 1 included in a light detection device 5, an electronic apparatus 7, etc. FIG. 2 illustrates the configuration of the example of the quantum dot 1 illustrated in FIG. 1 when viewed from another angle.

As illustrated in FIGS. 1 and 2, the quantum dot 1 includes a core-shell structure. This quantum dot 1 includes a core 2 and a shell 3. In addition, the quantum dot 1 is provided with an organic ligand 4.

### (2) Configuration of Core 2

The core 2 includes a semiconductor nanoparticle including a compound semiconductor. In the first embodiment, the core 2 includes a compound semiconductor including a combination of three or more elements selected from Groups I, II, III, IV, V, and VI. Here, the core 2 includes CuInSe₂.

In addition, the core 2 may include a III-V compound semiconductor or a II-VI compound semiconductor. Specifically, PbS may be used for the core 2.

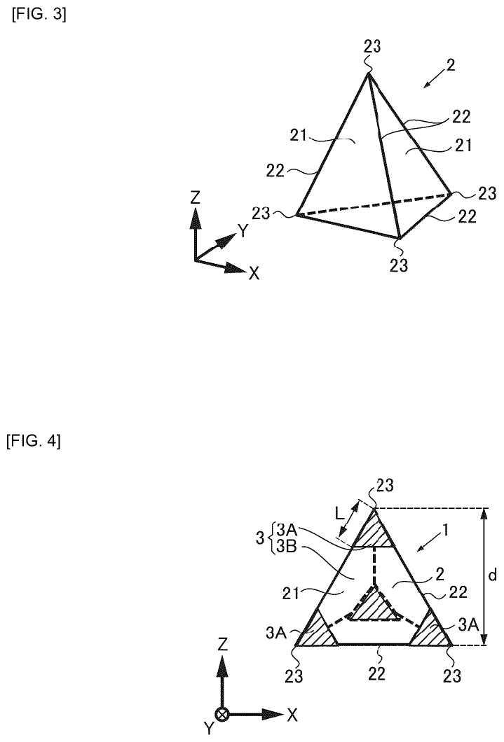

FIG. 3 illustrates one example of a crystal structure of the core 2.

Here, the core 2 of the quantum dot 1 has a tetrahedral shape that is one of polyhedral shapes, as illustrated in FIG. 3. That is, the crystal structure of the core 2 has a tetrahedral shape.

To describe in more detail, the core 2 has an outer shape including multiple surfaces 21, multiple edges 22, and multiple vertices 23. Here, the surfaces 21 include one bottom surface having a triangle shape, and three side surfaces each similarly having a triangle shape. Whether or not each of the bottom surface and the side surfaces included in the surfaces 21 has a regular triangle shape is optional.

The edge 22 is provided between one surface 21 and another surface 21 adjacent to the one surface 21. For example, one edge 22 is provided between the surface 21 corresponding to the bottom surface and the surface 21 corresponding to one side surface adjacent to this surface 21. Similarly, another edge 22 is provided between two surfaces 21 corresponding to two adjacent side surfaces. Six edges 22 are provided in total.

The vertex 23 is a part at which multiple edges 22 intersect with each other and converge. Here, three edges 22 converge to form one vertex 23. Four vertices 23 are provided in total.

### (3) Configuration of Shell 3

The shell 3 is provided at the surface 21 of the core 2. Here, ZnS is used for the shell 3. Although a defect (dangling bond) having high reactivity is present on the surface 21 of the core 2, the defect is made inactive owing to the organic ligand 4 that covers the surface 21. The organic ligand 4 includes a compound that forms coordinate bond with metal.

Meanwhile, when PbS is used for the core 2, PbS or PbSe may be used for the shell 3.

Typically, a density of coverage with the organic ligand 4 at the surface 21 of the core 2 is low at a part around the vertex 23, and is higher at a middle part of the surface 21 than at the part around the vertex 23. That is, at the part around the vertex 23, the density of coverage with the organic ligand 4 is low, and hence, electron-hole recombination occurs easily and the light emitting property or the light receiving property tends to deteriorate.

FIG. 4 illustrates one example of a basic configuration of the core 2 and the shell 3 of the quantum dot 1.

In the first embodiment, the shell 3 includes a shell 3A provided at the part around the vertex 23 of the surface 21, and a shell 3B provided at the middle part of the surface 21.

Here, the part around the vertex 23 is present within a range of a length L from the vertex 23 as illustrated in FIG. 4. The length L is set to d/4 (L≤d/4) where d is a diameter of the whole of the core 2 defined by the Feret diameter (Feret diameter).

In addition, the shell 3A is thicker than the shell 3B. To describe in more detail, the shell 3A provided at the part around the vertex 23 has a thickness in a vertical direction with respect to the surface 21, and the thickness is greater than a thickness, in the same direction, of the shell 3B provided at the middle part of the surface 21.

As one example, the thickness of the shell 3A is greater than or equal to 0.2 nm and less than or equal to 2.0 nm. In addition, the thickness of the shell 3B is greater than 0 and less than or equal to 0.2 nm.

The shell 3A is provided at each part around the vertex 23 of the core 2. That is, here, because the core 2 has the tetrahedral shape, the shell 3A is provided at each of the four parts around the vertices 23 in total of the core 2.

### (4) Specific Configuration of Quantum Dot 1 and Quantum Dot Ensemble 10

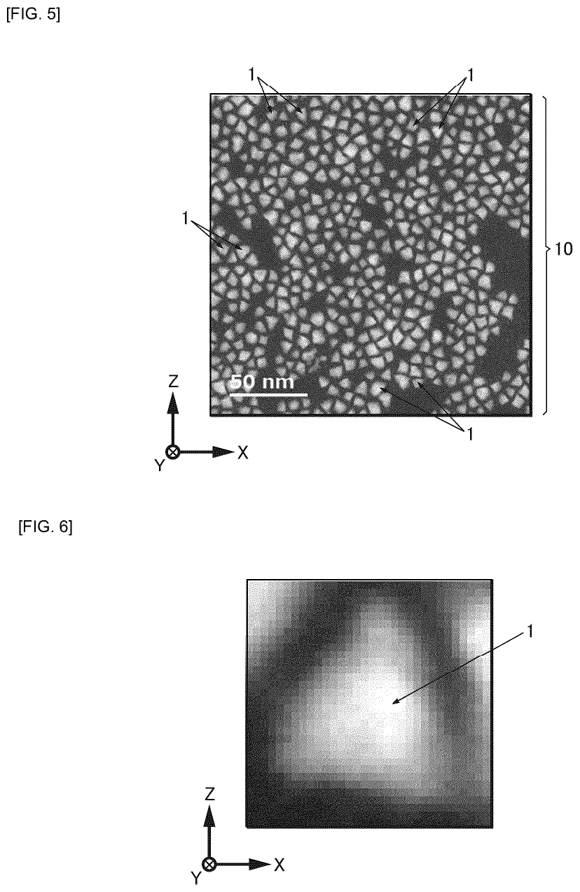

FIG. 5 illustrates an HAADF image of one example of the quantum dot ensemble 10 that is taken using a high-angle annular dark field scanning transmission electron microscope (hereinafter, simply referred to as “HAADF-STEM”).

As illustrated in the HAADF image in FIG. 5, the quantum dot ensemble 10 is an ensemble of quantum dots 1 shaped in a layered shape in the arrowed Z direction. Each of the shaped pieces in the quantum dot ensemble 10 is the quantum dot 1.

FIG. 6 illustrates an enlarged HAADF image of one example of one quantum dot 1 of the quantum dot ensemble 10 illustrated in FIG. 5. As described above, in the first embodiment, the quantum dot 1 has the tetrahedral shape.

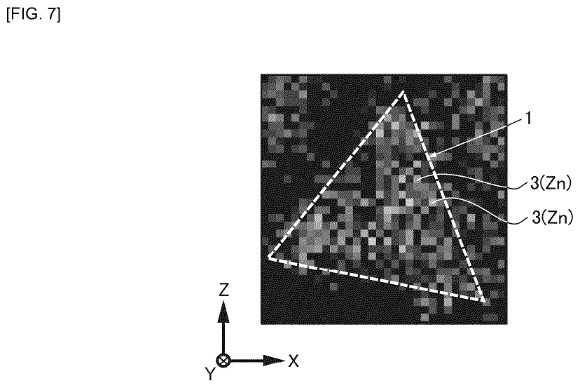

FIG. 7 is a diagram corresponding to FIG. 6, and illustrates one example of a distribution of a constituent element of the shell 3 measured by energy dispersive X-ray spectroscopy.

In the first embodiment, ZnS is used for the shell 3 as described above. Of the constituent elements of the shell 3, FIG. 7 illustrates a distribution of Zn.

### EXAMPLES AND COMPARATIVE EXAMPLES

Next, specific Examples of the quantum dot 1 according to the first embodiment will be described in detail with comparison with quantum dots according to comparative examples.

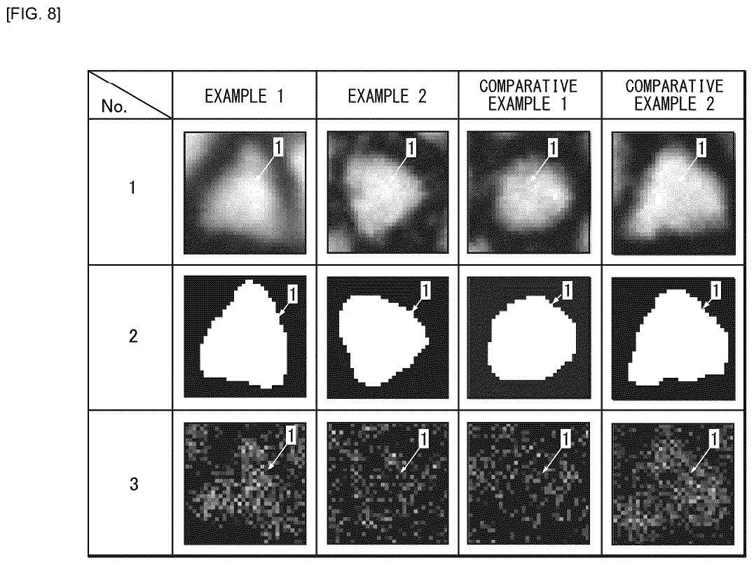

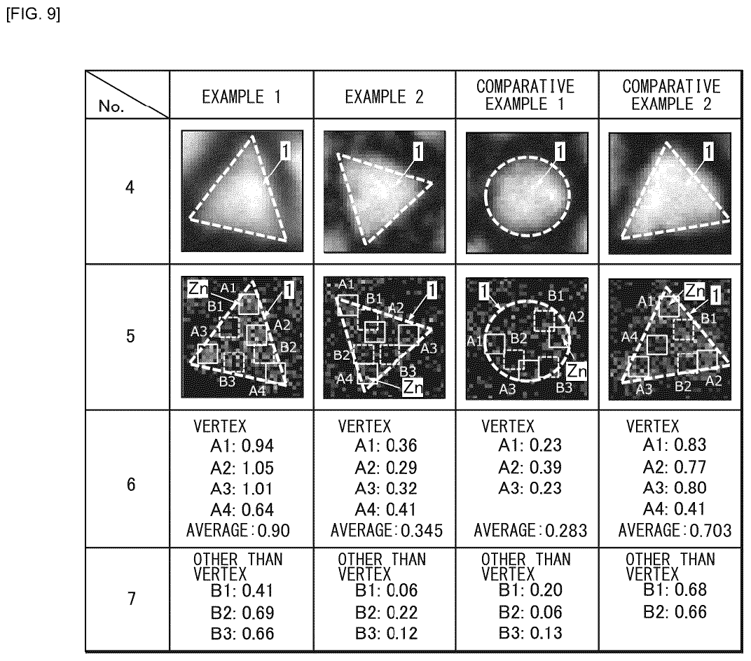

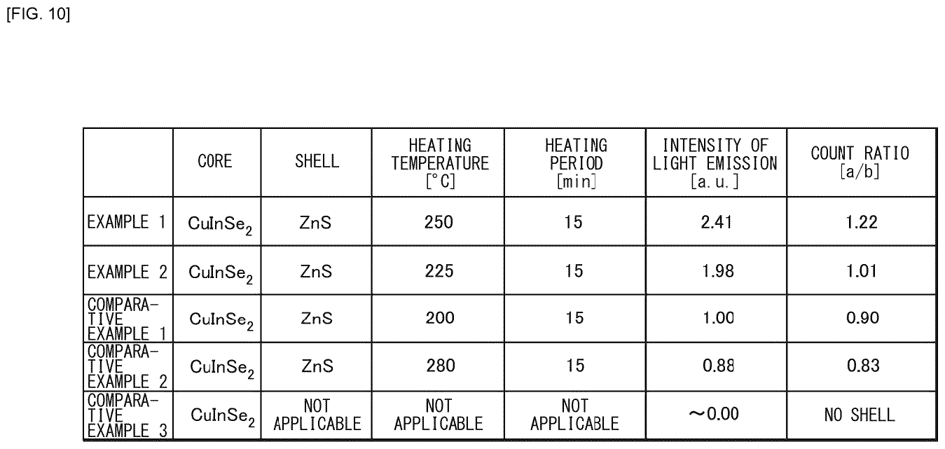

FIG. 8 is a first table used to describe configurations of quantum dots according to Examples of the first embodiment and configurations of the quantum dots according to the comparative examples. FIG. 9 is a second table continuing from FIG. 8. FIG. 10 is a table used to describe characteristics of the quantum dots according to Examples of the first embodiment and characteristics of the quantum dots according to the comparative examples.

### Comparative Example 1

First, as indicated in FIG. 10, in the quantum dot according to Comparative example 1, the core included CuInSe₂ and the shell included ZnS, as with the quantum dot 1 according to the first embodiment. In fabrication (manufacturing) of the shell, a heating temperature was set to 200° C., and a heating period was set to 15 minutes.

In FIG. 8, the first row in the vertical direction indicates an HAADF image of each of the quantum dots imaged using an HAADF-STEM. The second row in the vertical direction indicates an outline shape of each of the quantum dots determined using a mask. The third row in the vertical direction indicates the distribution of the constituent element of the shell provided at the surface of the core of each of the quantum dots. The constituent element is Zn.

In FIG. 9, the fourth row in the vertical direction indicates diagrams in each of which the HAADF image of the quantum dot indicated in the first row in the vertical direction and the outline shape of the quantum dot indicated in the second row in the vertical direction are superimposed on each other. The fifth row in the vertical direction indicates diagrams each including the distribution of the constituent element of the shell indicated in the third row in the vertical direction, and the outline shape of the quantum dot indicated in the fourth row in the vertical direction.

Furthermore, the sixth row in the vertical direction indicates the characteristic X-ray count rates of the constituent element of the shell at a part A (region surrounded by a solid line) around the vertex of the core indicated in the fifth row in the vertical direction. That is, in the tetrahedral shape, four vertices exist, and it indicates the characteristic X-ray count rate of Zn in each of parts A1 to A4 around the vertices measured by energy dispersive X-ray spectroscopy.

In addition, the seventh row in the vertical direction indicates the characteristic X-ray count rates of the constituent element of the shell in a middle part B (region surrounded by a dashed line) of the surface of the core indicated in the fifth row in the vertical direction. It indicates the characteristic X-ray count rate of Zn in each of middle parts B1 to B3 or middle parts B1 and B2 depending on measurement situations.

Here, in Comparative example 1, a measurement was performed to obtain an average value m of the characteristic X-ray count rates in the whole of the quantum dot, a standard deviation sd thereof, and a sum b of the average value m and the standard deviation sd.
m: 0.0773926
sd: 0.23616
b: 0.3135526

Meanwhile, as indicated in the sixth row in the vertical direction in FIG. 9, a measurement was performed to obtain an average value a of the characteristic X-ray count rates of the constituent element of the shell at the part around the vertex of the quantum dot.
a: 0.283333333

From these results, the average value a of the characteristic X-ray count rates of the constituent element of the shell at the part around the vertex of the quantum dot was smaller than the sum b of the average value m and the standard deviation sd of the characteristic X-ray count rates of the constituent element of the shell in the whole of the core, as indicated in FIG. 10. Specifically, a ratio (a/b) between the average value a and the sum b was smaller than 1, and was approximately 0.90.

This result of the ratio between the average value a and the sum b being smaller than 1 means that the thickness of the shell provided at the part around the vertex was smaller than the thickness of the shell provided at a part other than the part around the vertex. Here, the thickness of the shell refers to the thickness of the shell in the vertical direction with respect to the surface of the core.

In addition, intensity of light emission of the quantum dot according to Comparative example 1 is regarded as “1,” and is used as a reference value in comparison.

### Comparative Example 2

In the quantum dot according to Comparative example 2, the core included CuInSe₂ and the shell included ZnS, as with the quantum dot according to Comparative example 1. In fabrication of the shell, the heating temperature was set to 280° C., and the heating period was set to 15 minutes.

The HAADF images, the outline shapes, the distributions of the constituent elements of the shells, etc. in the first row in the vertical direction to the seventh row in the vertical direction according to Comparative example 2 indicated in FIGS. 8 and 9 are similar to those of Comparative example 1.

Here, in Comparative example 2, a measurement was performed to obtain the average value m of the characteristic X-ray count rates in the whole of the quantum dot, the standard deviation sd thereof, and the sum b of the average value m and the standard deviation sd.
m: 0.309814
sd: 0.536565
b: 0.846379

Meanwhile, as indicated in the sixth row in the vertical direction in FIG. 9, a measurement was performed to obtain the average value a of the characteristic X-ray count rates of the constituent element of the shell at the part around the vertex of the quantum dot.
a: 0.7025

From these results, the average value a of the characteristic X-ray count rates of the constituent element of the shell at the part around the vertex of the quantum dot was smaller than the sum b of the average value m and the standard deviation sd of the characteristic X-ray count rates of the constituent element of the shell in the whole of the core, as indicated in FIG. 10. Specifically, the ratio (a/b) between the average value a and the sum b was smaller than 1, and was approximately 0.83.

This result of the ratio between the average value a and the sum b being smaller than or equal to 1 means that the thickness of the shell provided at the part around the vertex was smaller than the thickness of the shell provided at a part other than the part around the vertex.

In addition, the intensity of light emission of the quantum dot according to Comparative example 2 was “0.88” with the reference being set to the intensity of light emission of the quantum dot according to Comparative example 1.

### Comparative Example 3

In the quantum dot according to Comparative example 3, the core included CuInSe₂, as with the quantum dot according to Comparative example 1. However, the shell was not provided. Thus, heating treatment was not performed in fabrication of the quantum dot.

In the quantum dot according to Comparative example 3, as indicated in FIG. 10, no constituent element of the shell existed, and the intensity of light emission of the quantum dot was “0.00” (less than 1/100) with the reference being set to the intensity of light emission of the quantum dot according to Comparative example 1.

### Example 1

In the quantum dot 1 according to Example 1 of the first embodiment, the core 2 included CuInSe₂ and the shell 3 included ZnS, as with the quantum dot according to Comparative example 1. In fabrication of the shell 3, the heating temperature was set to 250° C., and the heating period was set to 15 minutes.

The HAADF images, the outline shapes, the distributions of the constituent elements of the shells, etc. in the first row in the vertical direction to the seventh row in the vertical direction according to Example 1 indicated in FIGS. 8 and 9 are similar to those of Comparative example 1.

Here, in Example 1, a measurement was performed to obtain the average value m of the characteristic X-ray count rates of the whole of the quantum dot 1, the standard deviation sd thereof, and the sum b of the average value m and the standard deviation sd.
m: 0.248779
sd: 0.488565
b: 0.737344

Meanwhile, as indicated in the sixth row in the vertical direction in FIG. 9, a measurement was performed to obtain the average value a of the characteristic X-ray count rates of the constituent element of the shell 3 at the part around the vertex 23 of the quantum dot 1.
a: 0.9

From these results, as indicated in FIG. 10, the average value a of the characteristic X-ray count rates of the constituent element of the shell 3 at the part around the vertex 23 of the quantum dot 1 was greater than the sum b of the average value m and the standard deviation sd of the characteristic X-ray count rates of the constituent element of the shell 3 in the whole of the core 2. Specifically, the ratio (a/b) between the average value a and the sum b was greater than or equal 1, and was approximately 1.22.

This result of the ratio between the average value a and the sum b being greater than or equal to 1 means that the thickness of the shell 3A provided at the part around the vertex 23 was greater than the thickness of the shell 3B provided at a part other than the part around the vertex 23.

In addition, the intensity of light emission of the quantum dot 1 according to Example 1 was “2.41” with the reference being set to the intensity of light emission of the quantum dot according to Comparative example 1.

### Example 2

In the quantum dot 1 according to Example 2 of the first embodiment, the core 2 included CuInSe₂ and the shell 3 included ZnS, as with the quantum dot 1 according to Example 1. In fabrication of the shell 3, the heating temperature was set to 225° C., and the heating period was set to 15 minutes.

The HAADF images, the outline shapes, the distributions of the constituent elements of the shells, etc. in the first row in the vertical direction to the seventh row in the vertical direction according to Example 2 indicated in FIGS. 8 and 9 are similar to those of Example 1.

Here, in Example 2, a measurement was performed to obtain the average value m of the characteristic X-ray count rates in the whole of the quantum dot 1, the standard deviation sd thereof, and the sum b of the average value m and the standard deviation sd.
m: 0.0895996
sd: 0.250545
b: 0.3401446

Meanwhile, as indicated in the sixth row in the vertical direction in FIG. 9, a measurement was performed to obtain the average value a of the characteristic X-ray count rates of the constituent element of the shell 3 at the part around the vertex 23 of the quantum dot 1.
a: 0.345

From these results, as indicated in FIG. 10, the average value a of the characteristic X-ray count rates of the constituent element of the shell 3 at the part around the vertex 23 of the quantum dot 1 was greater than the sum b of the average value m and the standard deviation sd of the characteristic X-ray count rates of the constituent element of the shell 3 in the whole of the core 2. Specifically, the ratio (a/b) between the average value a and the sum b was greater than or equal to 1, and was approximately 1.01.

This result of the ratio between the average value a and the sum b being greater than or equal to 1 means that the thickness of the shell 3A provided at the part around the vertex 23 was greater than the thickness of the shell 3B provided at a part other than the part around the vertex 23.

In addition, the intensity of light emission of the quantum dot 1 according to Example 2 was “1.98” with the reference being set to the intensity of light emission of the quantum dot according to Comparative example 1.

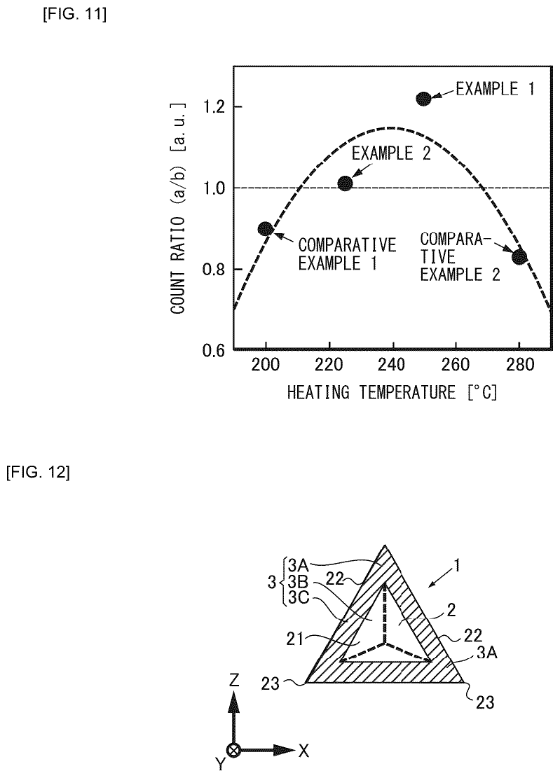

FIG. 11 illustrates a relationship between the heating temperature and the thicknesses of the shell at the part around the vertex of each of the core 2 and the core in each of the quantum dots 1 according to Examples 1 and 2 and the quantum dots according to Comparative examples 1 and 2. The horizontal axis indicates the heating temperature [° C.] in fabrication of each of the shell 3 and the shell. The vertical axis indicates the ratio (a/b) [a. u.] between the average value a and the sum b.

In FIG. 11, numerical values of the ratio (a/b) obtained on the basis of results of the measurement for each of Examples 1 and 2 and Comparative examples 1 and 2 are plotted, and FIG. 11 illustrates a curve resulting from fitting these numerical values into a two-dimensional function.

Thus, in the quantum dot 1, when the heating temperature in fabricating the shell 3 is set to be higher than or equal to 213° C. and lower than or equal to 264° C., it is possible to form the shell 3 in which the thickness of the shell 3A at the part around the vertex 23 is greater than the thickness of the shell 3B at a part other than the part around the vertex 23. That is, with the quantum dot 1, it is possible to improve the light emitting property or the light receiving property.

### Workings and Effects

The quantum dot 1 according to the first embodiment includes the core 2 and the shell 3, as illustrated in FIGS. 1 to 4. The core 2 includes the compound semiconductor, and has a polyhedral shape including the multiple surfaces 21 and the vertex 23 at which the multiple edges 22 between the surfaces 21 adjacent to each other converge. The shell 3 is provided at the surfaces 21, and has the thickness at the part around the vertex 23 in the vertical direction with respect to the surfaces 21, and the thickness is greater than the thickness at a part other than the part around the vertex 23 in the same direction. In other words, the thickness of the shell 3A provided at the part around the vertex 23 is greater than the thickness of the shell 3B provided at the middle part of the surface 21.

In the case of the quantum dot 1, this makes it possible to increase the thickness of the shell 3A of the shell 3 at the part around the vertex 23 of the core 2 where the density of coverage with the organic ligand 4 is low. Thus, it is possible to inactivate the defect existing on the surfaces 21 of the core 2 and having high reactivity, which makes it possible to improve the light emitting property or the light receiving property of the quantum dot 1.

In addition, in the quantum dot 1, the average value a of the characteristic X-ray count rates of the constituent element of the shell 3 measured at the part around the vertex 23 of the core 2 by energy dispersive X-ray spectroscopy is greater than the sum b of the average value m and the standard deviation sd of the characteristic X-ray count rates of the constituent element of the shell 3 measured in the whole of the core 2 by energy dispersive X-ray spectroscopy.

In the case of the quantum dot 1, this makes it possible to increase the thickness of the shell 3A of the shell 3 at the part around the vertex 23 of the core 2 where the density of coverage with the organic ligand 4 is low.

Furthermore, in the quantum dot 1, the part around the vertex 23 is present within the range of d/4 from the vertex 23 where the diameter of the whole of the core 2 defined by the Feret diameter is d, as illustrated in FIG. 4. The density of coverage with the organic ligand 4 is low at the part around the vertex 23.

Thus, it is possible to increase the thickness of the shell 3A of the shell 3 at the part around the vertex 23 of the core 2 where the density of coverage with the organic ligand 4 is low.

In addition, in the quantum dot 1, the core 2 has the tetrahedral shape including four surfaces 21. In the quantum dot 1 having such a shape, it is possible to inactivate the defect existing on the surfaces 21 of the core 2 and having high reactivity, which makes it possible to improve the light emitting property or the light receiving property of the quantum dot 1.

In addition, in the quantum dot 1, the core 2 includes the compound semiconductor including the combination of three or more elements selected from Groups I, II, III, IV, V, and VI. For example, the core 2 includes CuInSe₂. In this case, the shell 3 includes ZnS.

Meanwhile, the core 2 of the quantum dot 1 may include the III-V compound semiconductor or the II-VI compound semiconductor. For example, the core 2 includes PbS. In this case, the shell 3 includes PbS or PbSe.

In the quantum dot 1 including such materials, it is possible to inactivate the defect existing on the surfaces 21 of the core 2 and having high reactivity, which makes it possible to improve the light emitting property or the light receiving property of the quantum dot 1.

Furthermore, the quantum dot ensemble 10 according to the first embodiment includes the ensemble of the quantum dot 1 shaped in the layered shape as illustrated in FIG. 5 in particular.

Because the quantum dot 1 makes it possible to improve the light emitting property or the light receiving property as described above, the quantum dot ensemble 10 as an ensemble thereof similarly makes it possible to improve the light emitting property or the light receiving property.

### Modification Example

A description will be given of a quantum dot 1 and a quantum dot ensemble 10 according to a modification example of the first embodiment.

Note that, for the quantum dot 1 and the quantum dot ensemble 10 according to this modification example as well as the second embodiment and subsequent embodiments, the same reference characters are attached to the same components or substantially the same components of the quantum dot 1 and the quantum dot ensemble 10 according to the first embodiment, and descriptions thereof will not be repeated.

FIG. 12 illustrates one example of the basic structure of the core 2 and the shell 3 of the quantum dot 1.

In the quantum dot 1 according to the modification example, the shell 3 includes a shell 3C in addition to the shell 3A and the shell 3B, as illustrated in FIG. 12. The shell 3C is provided at a part around the edge 22 of the core 2, and is thicker than the thickness of the shell 3B, as with the shell 3A.

In addition, the quantum dot ensemble 10 is an ensemble in which the quantum dots 1 formed in such a manner are shaped in the layered shape (see FIG. 5).

Components other than the components described above are the same as or substantially the same as the components of the quantum dot 1 and the quantum dot ensemble 10 according to the first embodiment.

With the quantum dot 1 and the quantum dot ensemble 10 according to the modification example of the first embodiment, it is possible to achieve workings and effects similar to the workings and effects achieved by the quantum dot 1 and the quantum dot ensemble 10 according to the first embodiment.

Furthermore, in the quantum dot 1 and the quantum dot ensemble 10, the shell 3C is also provided at the part around the edge 22 of the core 2. This makes it possible to further improve the light emitting property or the light receiving property.

### 2. Second Embodiment

A quantum dot 1 and a quantum dot ensemble 10 according to the second embodiment of the present disclosure will be described with reference to FIGS. 13 to 15.

The quantum dot 1 according to the second embodiment includes the core 2 and the shell 3, as with the quantum dot 1 according to the first embodiment.

FIG. 13 illustrates one example of a crystal structure of the core 2 of the quantum dot 1 according to the second embodiment.

Here, the core 2 of the quantum dot 1 has a hexahedral shape that is one of polyhedral shapes, as illustrated in FIG. 13. That is, the crystal structure of the core 2 has a hexahedral shape.

Specifically, the core 2 has an outer shape including multiple surfaces 21, multiple edges 22, and multiple vertices 23. Here, the surfaces 21 include one bottom surface having a quadrilateral shape, one top surface having a quadrilateral shape, and four side surfaces each similarly having a quadrilateral shape. Whether or not each of the bottom surface, the top surface, and the side surfaces included in the surfaces 21 has a square shape is optional.

The edge 22 is provided between one surface 21 and another surface 21 adjacent to the one surface 21. Twelve edges 22 are provided in total.

The vertex 23 is a part at which multiple edges 22 intersect with each other and converge. Here, three edges 22 converge to form one vertex 23. Eight vertices 23 are provided in total.

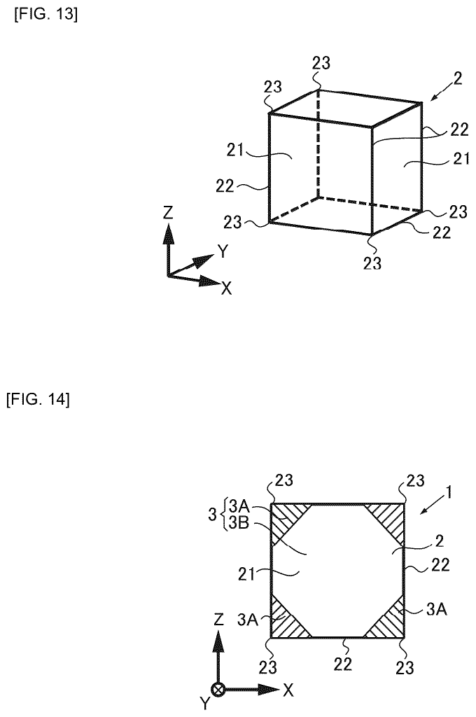

FIG. 14 illustrates one example of the basic structure of the core 2 and the shell 3 of the quantum dot 1.

In the second embodiment, the shell 3 includes the shell 3A provided at the part around the vertex 23 of the surface 21 and the shell 3B provided at the middle part of the surface 21, as with the quantum dot 1 according to the first embodiment.

The shell 3A is thicker than the shell 3B. To describe in more detail, the thickness, in the vertical direction with respect to the surface 21, of the shell 3A provided at the part around the vertex 23 is greater than the thickness, in the same direction, of the shell 3B provided at the middle part of the surface 21.

The shell 3A is provided at each of the parts around the vertices 23 of the core 2. That is, because the core 2 here has the hexahedral shape, the shell 3A is provided at each of eight parts around the vertices 23 in total of the core 2.

In addition, the quantum dot ensemble 10 is an ensemble in which the quantum dots 1 formed in such a manner are shaped in the layered shape (see FIG. 5).

Components other than the components described above are the same as or substantially the same as the components of the quantum dot 1 and the quantum dot ensemble 10 according to the first embodiment.

With the quantum dot 1 and the quantum dot ensemble 10 according to the second embodiment, it is possible to achieve workings and effects similar to the workings and effects achieved by the quantum dot 1 and the quantum dot ensemble 10 according to the first embodiment.

### Modification Example

A description will be given of a quantum dot 1 and a quantum dot ensemble 10 according to a modification example of the second embodiment.

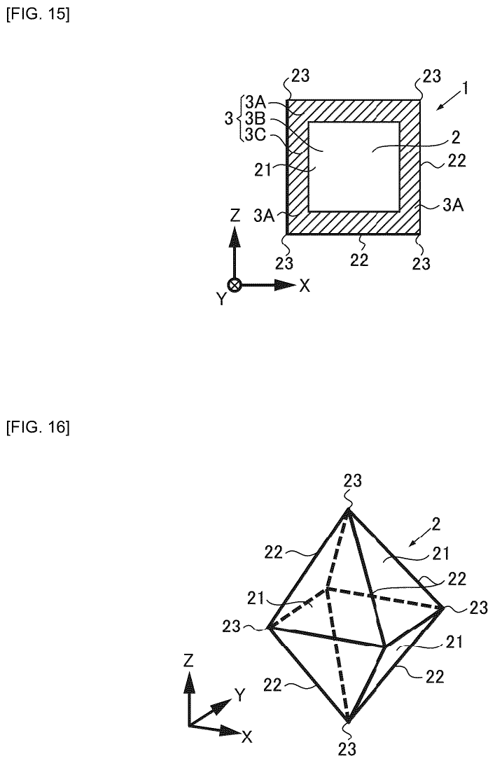

FIG. 15 illustrates one example of the basic structure of the core 2 and the shell 3 of the quantum dot 1.

In the quantum dot 1 according to the modification example, the shell 3 includes the shell 3C, in addition to the shell 3A and the shell 3B, as illustrated in FIG. 15. The shell 3C is provided at the part around the edge 22 of the core 2, and is thicker than the thickness of the shell 3B, as with the shell 3A.

In addition, the quantum dot ensemble 10 is an ensemble in which the quantum dots 1 formed in such a manner are shaped in the layered shape (see FIG. 5).

Components other than the components described above are the same as or substantially the same as the components of the quantum dot 1 and the quantum dot ensemble 10 according to the first embodiment.

With the quantum dot 1 and the quantum dot ensemble 10 according to the modification example of the second embodiment, it is possible to achieve workings and effects similar to the workings and effects achieved by the quantum dot 1 and the quantum dot ensemble 10 according to the modification example of the first embodiment.

### 3. Third Embodiment

A quantum dot 1 and a quantum dot ensemble 10 according to the third embodiment of the present disclosure will be described with reference to FIGS. 16 to 18.

The quantum dot 1 according to the third embodiment includes the core 2 and the shell 3, as with the quantum dot 1 according to the first embodiment.

FIG. 16 illustrates one example of the crystal structure of the core 2 of the quantum dot 1 according to the third embodiment.

Here, as illustrated in FIG. 16, the core 2 of the quantum dot 1 has an octahedral shape that is one of polyhedral shapes. That is, the crystal structure of the core 2 has an octahedral shape.

To describe in more detail, the core 2 has an outer shape including multiple surfaces 21, multiple edges 22, and multiple vertices 23. Here, the surfaces 21 include eight side surfaces each having a triangle shape. Whether or not each of the surfaces 21 has a regular triangle shape is optional.

The edge 22 is provided between one surface 21 and another surface 21 adjacent to this one surface 21. Twelve edges 22 are provided in total.

The vertex 23 is a part at which multiple edges 22 intersect with each other and converge. Here, four edges 22 converge to form one vertex 23. Six vertices 23 are provided in total.

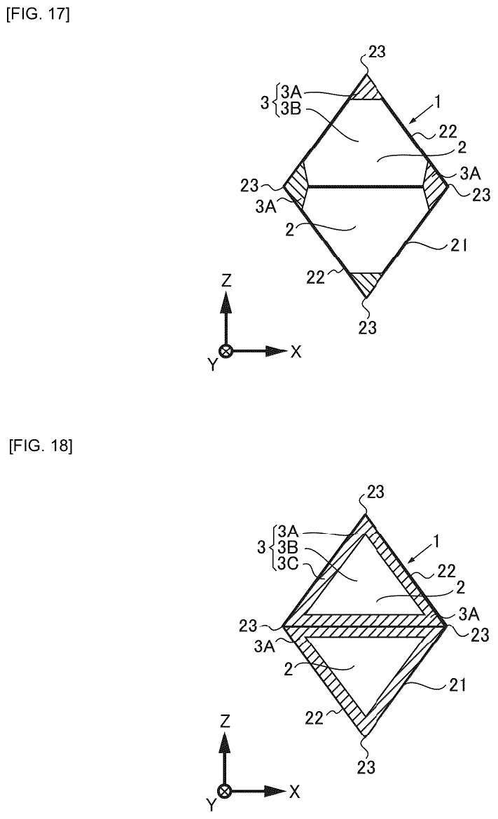

FIG. 17 illustrates one example of the basic structure of the core 2 and the shell 3 of the quantum dot 1.

In the third embodiment, the shell 3 includes the shell 3A provided at the part around the vertex 23 of the surface 21 and the shell 3B provided at the middle part of the surface 21, as with the quantum dot 1 according to the first embodiment.

The shell 3A is thicker than the shell 3B. To describe in more detail, the thickness, in the vertical direction with respect to the surface 21, of the shell 3A provided at the part around the vertex 23 is greater than the thickness, in the same direction, of the shell 3B provided at the middle part of the surface 21.

The shell 3A is provided at each of the parts around the vertices 23 of the core 2. That is, because the core 2 here has the octahedral shape, the shell 3A is provided at each of six parts around the vertices 23 in total of the core 2.

In addition, the quantum dot ensemble 10 is an ensemble in which the quantum dots 1 formed in such a manner are shaped in the layered shape (see FIG. 5).

Components other than the components described above are the same as or substantially the same as the components of the quantum dot 1 and the quantum dot ensemble 10 according to the first embodiment.

With the quantum dot 1 and the quantum dot ensemble 10 according to the third embodiment, it is possible to achieve workings and effects similar to the workings and effects achieved by the quantum dot 1 and the quantum dot ensemble 10 according to the first embodiment.

### Modification Example

A description will be given of a quantum dot 1 and a quantum dot ensemble 10 according to a modification example of the third embodiment.

FIG. 18 illustrates one example of the basic structure of the core 2 and the shell 3 of the quantum dot 1.

In the quantum dot 1 according to the modification example, the shell 3 includes the shell 3C, in addition to the shell 3A and the shell 3B, as illustrated in FIG. 18. The shell 3C is provided at the part around the edge 22 of the core 2, and is thicker than the thickness of the shell 3B, as with the shell 3A.

In addition, the quantum dot ensemble 10 is an ensemble in which the quantum dots 1 formed in such a manner are shaped in the layered shape (see FIG. 5).

Components other than the components described above are the same as or substantially the same as the components of the quantum dot 1 and the quantum dot ensemble 10 according to the first embodiment.

With the quantum dot 1 and the quantum dot ensemble 10 according to the modification example of the third embodiment, it is possible to achieve workings and effects similar to the workings and effects achieved by the quantum dot 1 and the quantum dot ensemble 10 according to the modification example of the first embodiment.

### 4. Fourth Embodiment

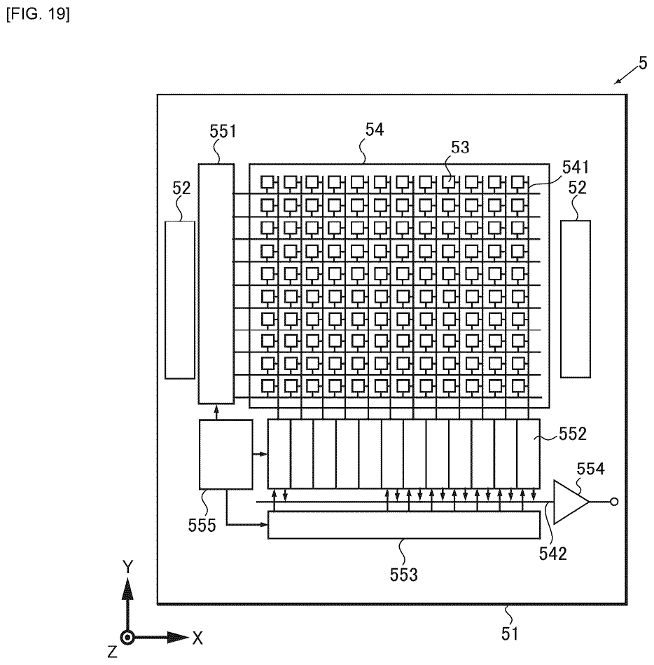

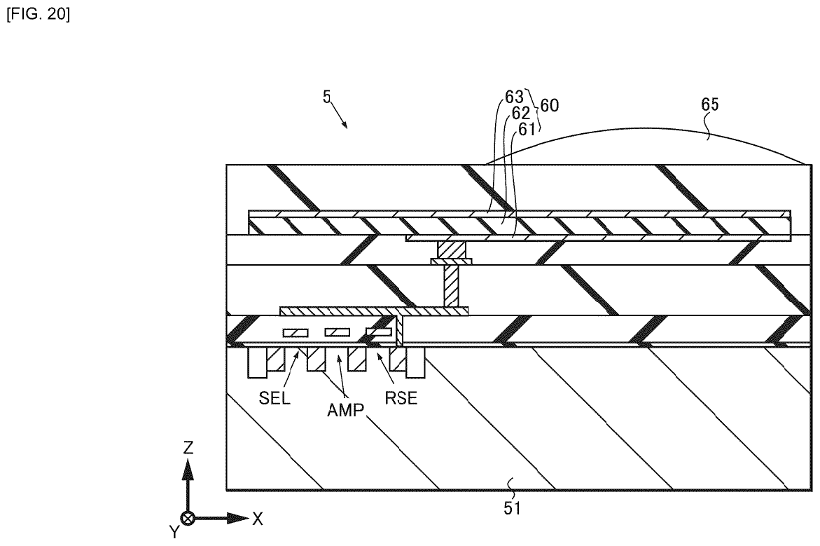

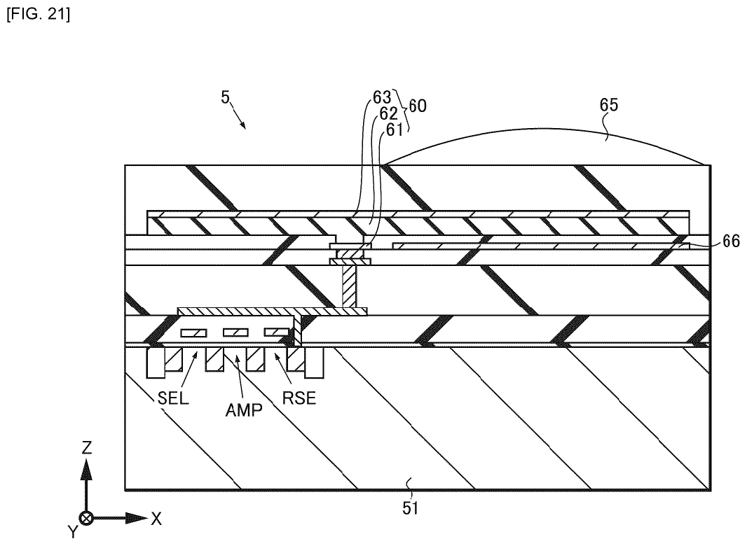

A light detection device 5 according to the fourth embodiment of the present disclosure will be described with reference to FIGS. 19 to 21. The light detection device 5 includes the quantum dot 1 and the quantum dot ensemble 10 according to any one of the first to third embodiments.

### [Layout Configuration of Light Detection Device 5]

FIG. 19 illustrates a schematic planar configuration of one example of the light detection device 5 according to the fourth embodiment. Here, the light detection device 5 is a CMOS solid-state imaging device.

The light detection device 5 includes a pixel region (what is called an imaging region) 54 and a peripheral circuit section. In the pixel region 54, pixels 53 including multiple photoelectric conversion elements are arranged regularly and two-dimensionally on a semiconductor substrate 51 such as a Si substrate. The pixel 53 includes a photoelectric conversion element and multiple pixel transistors. The pixel transistors each include what is called an insulated gate field effect transistor (IGFET).

The multiple pixel transistors include, for example, three transistors including a transfer transistor, a reset transistor, and an amplification transistor. In addition, by further adding a selection transistor, the pixel transistor may include four transistors.

A unit pixel has a typical equivalent circuit, and hence, a detailed description thereof will not be given.

Furthermore, the pixel 53 may have a shared pixel structure. This shared pixel structure includes multiple photoelectric conversion elements, multiple transfer transistors, one shared floating diffusion, and one shared pixel transistor of each kind.

The peripheral circuit section includes a vertical driving circuit 551, a column signal processing circuit 552, a horizontal driving circuit 553, an output circuit 554, a control circuit 555, etc.

The control circuit 555 receives an input clock and data used to give an instruction on an operating mode or the like, and outputs data regarding internal information or the like regarding the light detection device 5. That is, the control circuit 555 generates, for example, a clock signal and a control signal serving as a basis for an operation of the vertical driving circuit 551, the column signal processing circuit 552, the horizontal driving circuit 553, or the like, on the basis of a vertical synchronization signal, a horizontal synchronization signal, and a master clock. In addition, these signals are supplied to the vertical driving circuit 551, the column signal processing circuit 552, the horizontal driving circuit 553, and the like.

The vertical driving circuit 551 includes, for example, a shift register. The vertical driving circuit 551 selects a pixel drive wiring, and supplies the selected pixel drive wiring with a pulse adapted to drive the pixels 53. The pixels 53 are driven on a row unit basis. That is, the vertical driving circuit 551 sequentially selects and scans each of the pixels 53 of the pixel region 54 in the vertical direction on the row unit basis. A signal charge generated in accordance with the amount of light received by the photoelectric conversion element of each of the pixels 53 is supplied through a vertical signal line 541 to the column signal processing circuit 552 as a pixel signal.

The column signal processing circuit 552 is disposed, for example, for each column of the pixels 53. In the column signal processing circuit 552, signal processing such as noise reduction is performed for each pixel column on a signal outputted from the pixels 53 for one line. That is, the column signal processing circuit 552 performs signal processing such as CDS (Correlated Double Sampling) that removes fixed pattern noises specific to the pixels 53, signal amplification, or A-D conversion. At an output stage of the column signal processing circuit 552, a horizontal selection switch, which is not illustrated in the drawing, is coupled between the output stage of the column signal processing circuit 552 and a horizontal signal line 542.

The horizontal driving circuit 553 includes, for example, a shift register. The horizontal driving circuit 553 sequentially outputs a horizontal scanning pulse to select each column signal processing circuit 552 in order, and a pixel signal is outputted from each of the column signal processing circuits 552 to the horizontal signal line 542.

The output circuit 554 performs signal processing on a signal sequentially supplied from each of the column signal processing circuits 552 through the horizontal signal line 542, and outputs it. For example, when only buffering is performed, the output circuit 554 performs, in some case, black level adjustment, column variation correction, various types of digital signal processing, or the like. An input-output terminal 52 sends or receives a signal between the light detection device 5 and the outside.

### [Vertical Cross-Sectional Configuration of Light Detection Device 5]

FIG. 20 illustrates one example of a vertical cross-sectional configuration of the light detection device 5.

The light detection device 5 includes the semiconductor substrate 51 as described above. Although a description is not given on a detailed structure, a selection transistor SEL, a reset transistor RSE, an amplification transistor AMP, and the like, which form the pixel transistor, are provided at the semiconductor substrate 51.

The upper side of the semiconductor substrate 51 serves as a light entrance side. A photoelectric conversion element 60 included in the pixel 53 is disposed on the semiconductor substrate 51. The photoelectric conversion element 60 includes a first electrode 61, a photoelectric conversion layer 62, and a second electrode 63 stacked on each other in order.

Note that a photodiode may be used in combination to configure the photoelectric conversion element 60.

The first electrode 61 includes a transparent electrode material. For the transparent electrode material, for example, ITO may be used. The first electrode 61 is coupled to the pixel transistor through a wiring to which no reference character is attached.

The photoelectric conversion layer 62 is a light detection element. The photoelectric conversion layer 62 includes the quantum dot ensemble 10 according to any of the first to third embodiments. As described above, the quantum dot ensemble 10 is an ensemble in which core-shell quantum dots 1 are shaped in the layered shape.

The second electrode 63 includes a transparent electrode material. For example, the second electrode 63 may include ITO, as with the first electrode 61.

An optical lens 65 is disposed on the photoelectric conversion element 60 with a protective film, to which no reference character is attached, being interposed between them. What is called an on-chip lens is used for the optical lens 65.

### [Modification Example of Light Detection Device 5]

FIG. 21 illustrates one example of a vertical cross-sectional configuration of a light detection device 5 according to a modification example of the fourth embodiment.

In the light detection device 5, a charge accumulation electrode 66 that is opposed to the photoelectric conversion layer 62 is disposed below the photoelectric conversion layer 62 of the photoelectric conversion element 60 with a dielectric body, to which no reference character is attached, being interposed between them. The charge accumulation electrode 66 includes, for example, a transparent electrode material, as with the first electrode 61. With this charge accumulation electrode 66, it is possible to increase the amount of charge accumulated at the photoelectric conversion element 60.

### Workings and Effects

The light detection device 5 according to the fourth embodiment includes the photoelectric conversion element 60 serving as a light detection element, as illustrated in FIG. 20 or 21. The photoelectric conversion element 60 includes the first electrode 61, the photoelectric conversion layer 62, and the second electrode 63 stacked on each other in order. The photoelectric conversion layer 62 includes the quantum dot ensemble 10 according to any one of the first to third embodiments.

This makes it possible to improve the light emitting property or the light receiving property of the quantum dot 1, which makes it possible to improve the light emitting property or the light receiving property of the light detection device 5.

### 5. Fifth Embodiment

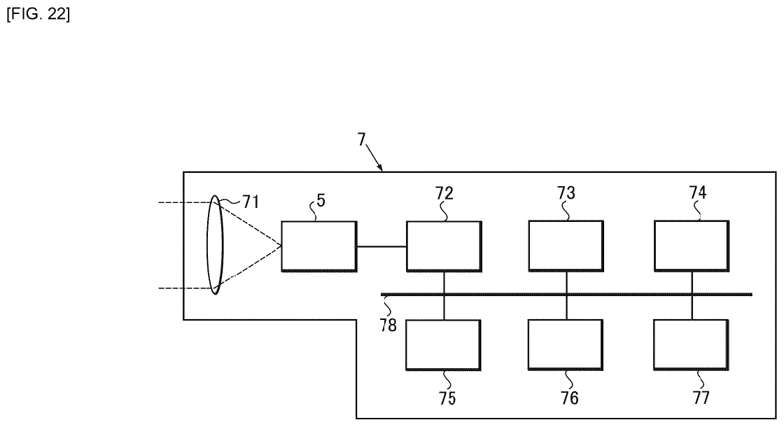

An electronic apparatus 7 according to the fifth embodiment of the present disclosure will be described with reference to FIG. 22. The electronic apparatus 7 includes the quantum dot 1 and the quantum dot ensemble 10 according to any one of the first to third embodiments, or includes the light detection device 5 according to the fourth embodiment. For example, the light detection device 5 is applicable to an imaging system such as a digital still camera or a digital video camera, a mobile phone apparatus having an imaging function, other apparatuses having an imaging function, or other various types of electronic apparatuses.

FIG. 22 is a block diagram illustrating an example of a configuration of the electronic apparatus 7 on which the light detection device 5 is mounted.

The electronic apparatus 7 includes an optical system 71, the light detection device 5, and a DSP (Digital Signal Processor) 72. In the electronic apparatus 7, the DSP 72, a display 73, an operation system 74, a memory 75, a recording device 76, and a power supply system 77 are coupled to each other through a bus 78. The electronic apparatus 7 is configured to capture a still image and a moving image.

The optical system 71 includes one or multiple lenses. The optical system 71 guides image light (incident light) from a subject to the light detection device 5 to form an image on a light receiving surface (sensor section) of the light detection device 5.

For example, the light detection device 5 according to the fourth embodiment is used for the light detection device 5. In the light detection device 5, electrons are accumulated for a certain period of time in accordance with the image formed on the light receiving surface through the optical system 71. In addition, a signal corresponding to the electrons accumulated in the light detection device 5 is supplied to the DSP 72.

The DSP 72 performs various types of signal processing on the signal from the light detection device 5 to acquire an image, and causes data regarding the image to be temporarily held in the memory 75. The data regarding the image held in the memory 75 is recorded in the recording device 76. In addition, the data regarding the image held in the memory 75 is supplied to the display 73, and the image is displayed on the display 73. Furthermore, the operation system 74 receives various types of operations performed by a user, and supplies operation signals to each of the blocks of the electronic apparatus 7. The power supply system 77 supplies electric power necessary to drive each of the blocks of the electronic apparatus 7.

### Workings and Effects

The electronic apparatus 7 according to the fifth embodiment includes the light detection device 5, as illustrated in FIG. 22. As described in relation to the light detection device 5 according to the fourth embodiment, the light detection device 5 includes the quantum dot ensemble 10.

This makes it possible to improve the light emitting property or the light receiving property of the electronic apparatus 7.

### 6. Example of Application to Mobile Body

The technique (present technique) according to the present disclosure is applicable to various products. For example, the technique according to the present disclosure may be implemented as an apparatus to be mounted on a mobile body of any one type of an automobile, an electric automobile, a hybrid electric automobile, a motorcycle, a bicycle, a personal mobility, an airplane, a drone, a vessel, a robot, or the like.

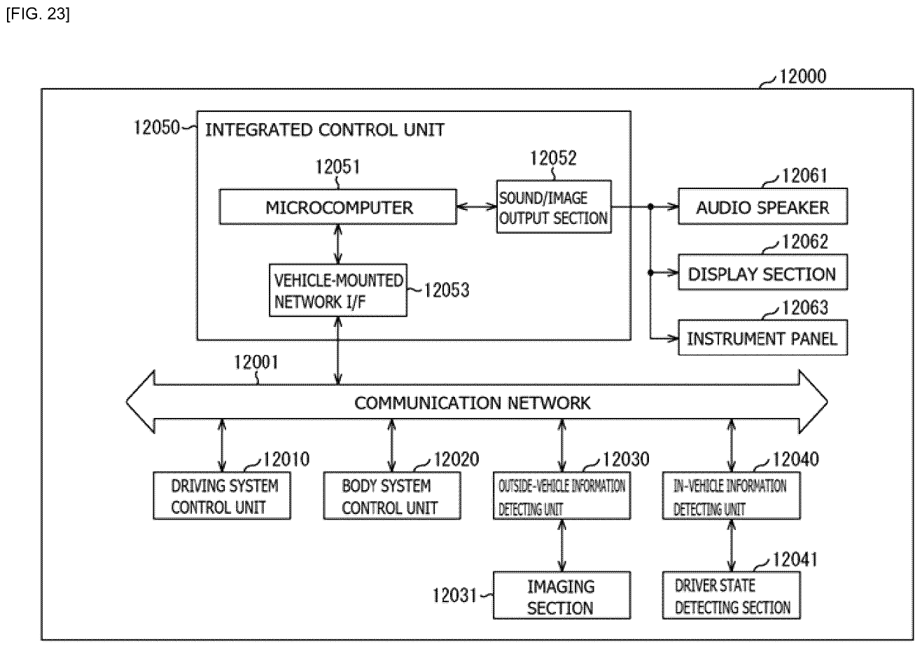

FIG. 23 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

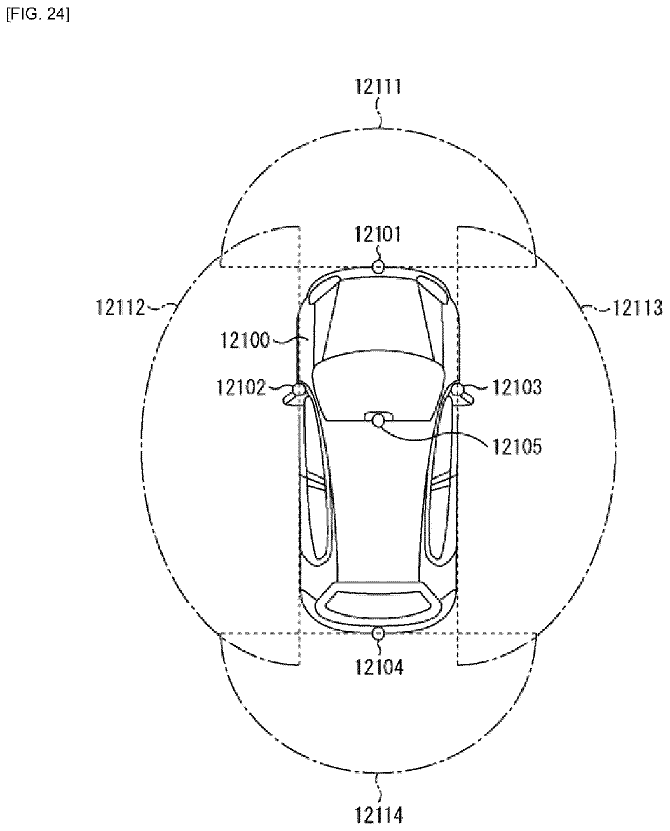

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

These are descriptions of one example of the vehicle control system to which the technique according to the present disclosure is applicable. Of the configurations that have been described above, the technique according to the present disclosure is applicable, for example, to the imaging section 12101 or the like. Specifically, the quantum dot according to the present disclosure is applicable to the imaging section 12101. By applying the technique according to the present disclosure to the imaging section 12101, it is possible to improve the light receiving property.

### 7. Example of Application to Endoscopic Surgery System

The technique (present technique) according to the present disclosure is applicable to various products. For example, the technique according to the present disclosure may be applied to an endoscopic surgery system.

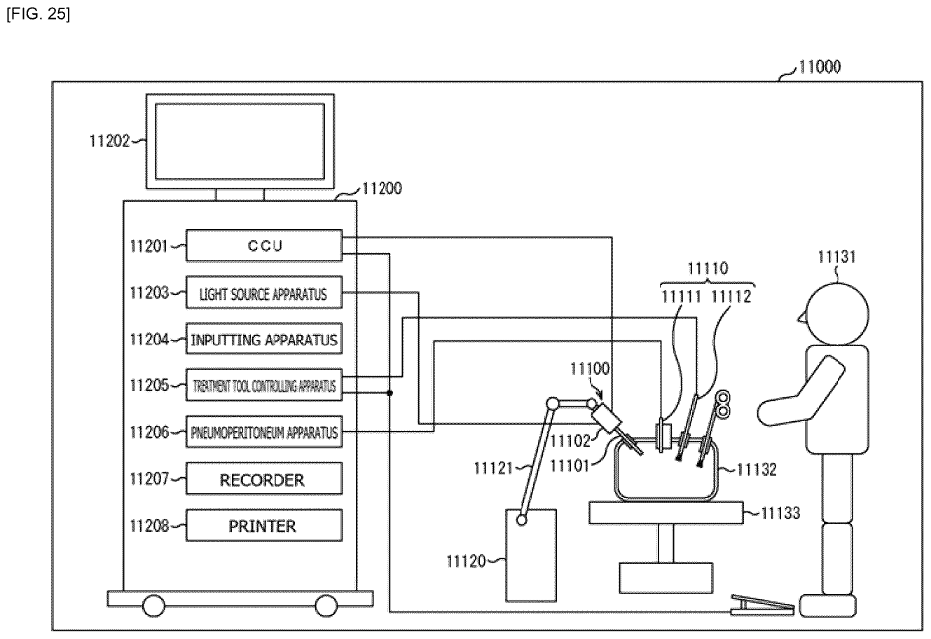

FIG. 25 is a view depicting an example of a schematic configuration of an endoscopic surgery system to which the technology according to an embodiment of the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

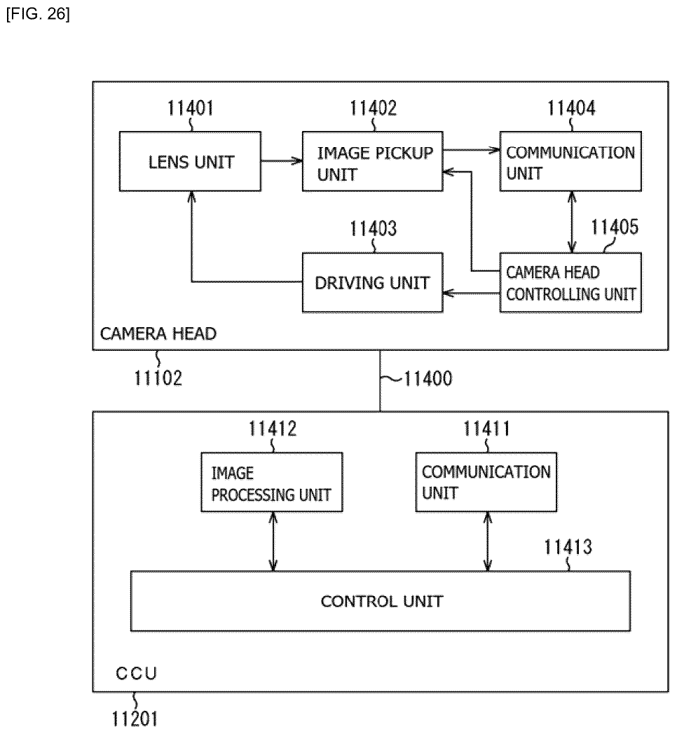

FIG. 26 is a block diagram depicting an example of a functional configuration of the camera head 11102 and the CCU 11201 depicted in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

These are descriptions of one example of the endoscopic surgery system to which the technique according to the present disclosure is applicable. Of the configurations that have been described above, the technique according to the present disclosure is applicable, for example, to the image pickup unit 11402 or the like. Specifically, the quantum dot according to the present disclosure is applicable to the image pickup unit 11402. By applying the technique according to the present disclosure to the image pickup unit 11402, it is possible to improve the light receiving property.

Note that, here, the description has been given of the endoscopic surgery system as one example. However, the technique according to the present disclosure may be applied to others, for example, to a microscope surgery system or the like.

### 8. Other Embodiments

The present technique is not limited to the embodiments described above, and various modifications may be made within a range not departing from the gist thereof.

For example, the embodiments described above describe the quantum dot and the quantum dot ensemble in which the core has the tetrahedral shape, the hexahedral shape, or the octahedral shape. However, it is possible to broadly apply the present technique to the quantum dot and the quantum dot ensemble including a core having a polyhedral shape other than the shapes described above.

A quantum dot according to a first aspect of the present disclosure includes a core and a shell. The core includes a compound semiconductor, and has a polyhedral shape. The polyhedral shape includes multiple surfaces and a vertex at which multiple edges between the surfaces adjacent to each other converge. The shell is provided at the surfaces and has a thickness at the part around the vertex in a vertical direction with respect to any one of the surfaces. The thickness is greater than a thickness at a part other than the part around the vertex in the same direction.

Thus, it is possible to increase the thickness of the shell at the part around the vertex of the core where a density of coverage with an organic ligand is low, which makes it possible to inactivate a defect being present on the surfaces of the core and having high reactivity. This makes it possible to improve light emitting property or light receiving property of the quantum dot.

A quantum dot ensemble according to a second aspect of the present disclosure includes an ensemble of a quantum dots shaped in a layered shape. The quantum dot makes it possible to improve the light emitting property or the light receiving property. Thus, similarly, the quantum dot ensemble as an ensemble makes it possible to improve the light emitting property or the light receiving property.

A light detection device according to a third aspect of the present disclosure includes a light detection element. The light detection element includes the quantum dot ensemble.

Thus, because it is possible to improve the light emitting property or the light receiving property of the quantum dot, it is possible to improve the light emitting property or the light receiving property of the light detection device.

The electronic apparatus according to a fourth aspect of the present disclosure includes a light detection device. The light detection device includes the quantum dot ensemble.

This makes it possible to improve the light emitting property or the light receiving property of the electronic apparatus.

### Configuration of Present Technique

The present technique includes the following configurations. With the following configurations being provided, it is possible to provide the quantum dot, the quantum dot ensemble, the light detection device, and the electronic apparatus that make it possible to improve the light emitting property or the light receiving property.

(1)

A quantum dot including:
a core including a compound semiconductor and having a polyhedral shape, the polyhedral shape including multiple surfaces and a vertex at which multiple edges between the surfaces adjacent to each other converge; and
a shell provided at the surfaces and having a thickness at the part around the vertex in a vertical direction with respect to any one of the surfaces, the thickness being greater than a thickness at a part other than the part around the vertex in the same direction.
   (2)

The quantum dot according to (1) described above, in which an average value a of characteristic X-ray count rates of a constituent element of the shell measured at the part around the vertex by energy dispersive X-ray spectroscopy is greater than a sum b of an average value and a standard deviation of characteristic X-ray count rates of the constituent element of the shell measured in whole of the core by the energy dispersive X-ray spectroscopy.

(3)

The quantum dot according to (1) or (2) described above, in which the part around the vertex is present within a range of d/4 from the vertex, where d is a diameter of whole of the core defined by a Feret diameter.

(4)

The quantum dot according to any one of (1) to (3) described above, in which the core has a tetrahedral shape including four the surfaces.

(5)

The quantum dot according to any one of (1) to (3) described above, in which the core has a hexahedral shape including six the surfaces.

(6)

The quantum dot according to any one of (1) to (3) described above, in which the core has an octahedral shape including eight the surfaces.

(7)

The quantum dot according to any one of (1) to (6) described above, in which the core includes the compound semiconductor including a combination of three or more elements selected from Groups I, II, III, IV, V, and VI.

(8)

The quantum dot according to any one of (1) to (7) described above, in which the core includes CuInSe2.

(9)

The quantum dot according to (8) described above, in which the shell includes ZnS.

(10)

The quantum dot according to any one of (1) to (6) described above, in which the core includes a III-V compound semiconductor or a II-VI compound semiconductor.

(11)

The quantum dot according to (10) described above, in which the core includes PbS.

(12)

The quantum dot according to (11) described above, in which the shell includes PbS or PbSe.

(13)

A quantum dot ensemble including
an ensemble of a quantum dot shaped in a layered shape, in which
the quantum dot includes
   a core including a compound semiconductor and having a polyhedral shape, the polyhedral shape including multiple surfaces and a vertex at which multiple edges between the surfaces adjacent to each other converge, and
   a shell provided at the surfaces and having a thickness at the part around the vertex in a vertical direction with respect to any one of the surfaces, the thickness being greater than a thickness at a part other than the part around the vertex in the same direction.
      (14)

A light detection device including
a light detection element including a first electrode, a photoelectric conversion layer, and a second electrode that are stacked on each other in order, the photoelectric conversion layer including a quantum dot ensemble, in which
the quantum dot ensemble includes an ensemble of a quantum dot shaped in a layered shape, and
the quantum dot includes
   a core including a compound semiconductor and having a polyhedral shape, the polyhedral shape including multiple surfaces and a vertex at which multiple edges between the surfaces adjacent to each other converge, and
   a shell provided at the surfaces and having a thickness at the part around the vertex in a vertical direction with respect to any one of the surfaces, the thickness being greater than a thickness at a part other than the part around the vertex in the same direction.
      (15)

An electronic apparatus including
a light detection element including a first electrode, a photoelectric conversion layer, and a second electrode that are stacked on each other in order, the photoelectric conversion layer including a quantum dot ensemble, in which
the quantum dot ensemble includes an ensemble of a quantum dot shaped in a layered shape, and
the quantum dot includes
   a core including a compound semiconductor and having a polyhedral shape, the polyhedral shape including multiple surfaces and a vertex at which multiple edges between the surfaces adjacent to each other converge, and
   a shell provided at the surfaces and having a thickness at the part around the vertex in a vertical direction with respect to any one of the surfaces, the thickness being greater than a thickness at a part other than the part around the vertex in the same direction.

The present application claims the benefit of Japanese Priority Patent Application JP2022-041757 filed with the Japan Patent Office on Mar. 16, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A quantum dot comprising:
a core including a compound semiconductor and having a polyhedral shape, the polyhedral shape including multiple surfaces and a vertex at which multiple edges between the surfaces adjacent to each other converge; and
a shell provided at the surfaces and having a thickness at a part around the vertex in a vertical direction with respect to any one of the surfaces, the thickness being greater than a thickness at a part other than the part around the vertex in same direction.

2. The quantum dot according to claim 1, wherein an average value a of characteristic X-ray count rates of a constituent element of the shell measured at the part around the vertex by energy dispersive X-ray spectroscopy is greater than a sum b of an average value and a standard deviation of characteristic X-ray count rates of the constituent element of the shell measured in whole of the core by the energy dispersive X-ray spectroscopy.

3. The quantum dot according to claim 1, wherein the part around the vertex is present within a range of d/4 from the vertex, where d is a diameter of whole of the core defined by a Feret diameter.

4. The quantum dot according to claim 1, wherein the core has a tetrahedral shape including four the surfaces.

5. The quantum dot according to claim 1, wherein the core has a hexahedral shape including six the surfaces.

6. The quantum dot according to claim 1, wherein the core has an octahedral shape including eight the surfaces.

7. The quantum dot according to claim 1, wherein the core includes the compound semiconductor including a combination of three or more elements selected from Groups I, II, III, IV, V, and VI.

8. The quantum dot according to claim 7, wherein the core includes CuInSe₂.

9. The quantum dot according to claim 8, wherein the shell includes ZnS.

10. The quantum dot according to claim 1, wherein the core includes a III-V compound semiconductor or a II-VI compound semiconductor.

11. The quantum dot according to claim 10, wherein the core includes PbS.

12. The quantum dot according to claim 11, wherein the shell includes PbS or PbSe.

13. A quantum dot ensemble comprising
an ensemble of a quantum dot shaped in a layered shape, wherein
the quantum dot includes
a core including a compound semiconductor and having a polyhedral shape, the polyhedral shape including multiple surfaces and a vertex at which multiple edges between the surfaces adjacent to each other converge, and
a shell provided at the surfaces and having a thickness at the part around the vertex in a vertical direction with respect to any one of the surfaces, the thickness being greater than a thickness at a part other than the part around the vertex in same direction.

14. A light detection device comprising
a light detection element including a first electrode, a photoelectric conversion layer, and a second electrode that are stacked on each other in order, the photoelectric conversion layer including a quantum dot ensemble, wherein
the quantum dot ensemble includes an ensemble of a quantum dot shaped in a layered shape, and
the quantum dot includes
a core including a compound semiconductor and having a polyhedral shape, the polyhedral shape including multiple surfaces and a vertex at which multiple edges between the surfaces adjacent to each other converge, and
a shell provided at the surfaces and having a thickness at the part around the vertex in a vertical direction with respect to any one of the surfaces, the thickness being greater than a thickness at a part other than the part around the vertex in same direction.

15. An electronic apparatus comprising
a light detection element including a first electrode, a photoelectric conversion layer, and a second electrode that are stacked on each other in order, the photoelectric conversion layer including a quantum dot ensemble, wherein
the quantum dot ensemble includes an ensemble of a quantum dot shaped in a layered shape, and
the quantum dot includes
a core including a compound semiconductor and having a polyhedral shape, the polyhedral shape including multiple surfaces and a vertex at which multiple edges between the surfaces adjacent to each other converge, and
a shell provided at the surfaces and having a thickness at the part around the vertex in a vertical direction with respect to any one of the surfaces, the thickness being greater than a thickness at a part other than the part around the vertex in same direction.
